(19) United States
(12) Patent Application Publication
(10) Pub. No.: US 2009/0023273 A1
(43) Pub. Date: Jan. 22, 2009

(54) METHOD OF FABRICATING SEMICONDUCTOR DEVICE

(75) Inventor: Han Choon LEE, Seoul (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/176,092

(22) Filed: Jul. 18, 2008

(30) Foreign Application Priority Data
Jul. 19, 2007 (KR) 10-2007-0072198

(51) Int. Cl. H01L 21/322

(52) U.S. Cl. 438/476; 257/E21.321

(57) ABSTRACT

A method of fabricating a semiconductor device comprising forming a transistor on a semiconductor substrate, forming an interlayer insulating film on the semiconductor substrate to cover the transistor, forming a passivation film on the interlayer insulating film, and annealing the semiconductor substrate having the passivation film in a gas atmosphere comprising at least one gas selected from the group of boron, silicon and hydrogen.

### CROSS-REFERENCE TO RELATED APPLICATION

This application claims the benefit of Korean Patent Application No. 10-2007-0072198, filed on Jul. 19, 2007, which is hereby incorporated by reference in its entirety as if fully set forth herein.

### BACKGROUND

1. Field of the Invention

Embodiments of the present invention relate to methods of fabricating a semiconductor device. More particularly, embodiments of the present invention relate to methods of fabricating a semiconductor device capable of efficiently restoring a silicon lattice.

2. Discussion of the Related Art

In general, a semiconductor device comprise a structure wherein active devices, such as transistors, or passive devices, such as capacitors, are formed on a substrate, with metal lines disposed above the active and passive devices in order to supply signals to the active and passive devices.

Such semiconductor devices may be fabricated through a variety of processes. During one particular ion implantation process that commonly used to manufacture semiconductor devices, the silicon lattice of the semiconductor device may become damaged, which may cause problems and reduce the performance of the resulting semiconductor device.

### SUMMARY

Accordingly, embodiments of the present invention are directed to methods of fabricating a semiconductor device that substantially obviates one or more problems, limitations, and/or disadvantages of the related art.

For example, disclosed embodiments are directed to a method of fabricating a semiconductor device that is capable of efficiently restoring the silicon lattice.

Additional advantages, objects, and features of the invention will be set forth in part in the description which follows and in part will become apparent to those having ordinary skill in the art upon examination of the following. Moreover, additional advantages, objects, and features of the invention may be learned from practice of the invention. Other advantages of the invention may be realized and attained by the structure particularly pointed out in the written description and claims as well as the appended drawings.

A first embodiment of the invention is directed to a method of fabricating a semiconductor device. The method comprises forming a transistor on a semiconductor substrate, forming an interlayer insulating film on the semiconductor substrate to cover the transistor, forming a passivation film on the interlayer insulating film, and annealing the semiconductor substrate having the passivation film in a gas atmosphere containing at least one of boron, silicon and hydrogen.

In the method of fabricating a semiconductor device according to disclosed embodiments, after the passivation film is formed on the interlayer insulating film, the semiconductor substrate undergoes an annealing process in a gas atmosphere containing at least one of boron, silicon and hydrogen. In this case, the damaged silicon lattice is restored and any fluorine gas remaining in the semiconductor substrate is removed, thereby improving the performance of the semiconductor device.

Another benefit of aspects of disclosed embodiments is that the annealing process can be performed at a lower temperature than that of an annealing process performed after vias and metal lines are formed.

Both the foregoing general description and the following detailed description of the present invention are exemplary and explanatory and are intended to provide further explanation of the invention as claimed.

### BRIEF DESCRIPTION OF THE DRAWINGS

The accompanying drawings are included to provide a further understanding of the invention and are incorporated in and constitute a part of this application. The drawings illustrate embodiment(s) of the invention and together with the description serve to explain the principle of the invention. In the drawings:

FIGS. 1A-1C are cross-sectional views illustrating a method for fabricating a CMOS image sensor according to the present invention; and

FIGS. 2A-2C are cross-sectional views illustrating a method of fabricating a CMOS transistor according to the present invention.

### DETAILED DESCRIPTION OF EXAMPLE EMBODIMENTS

Reference will now be made in detail to the preferred embodiments of the present invention, examples of which are illustrated in the accompanying drawings. Wherever possible, the same reference numbers will be used throughout the drawings to refer to the same or like parts.

### Method of Fabricating CMOS Image Sensor

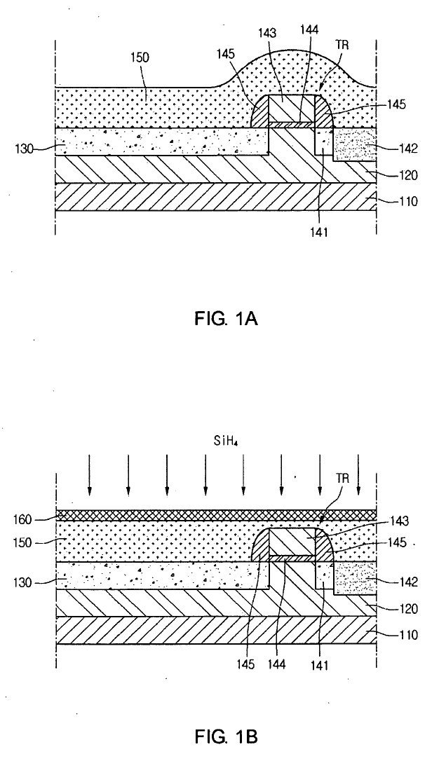

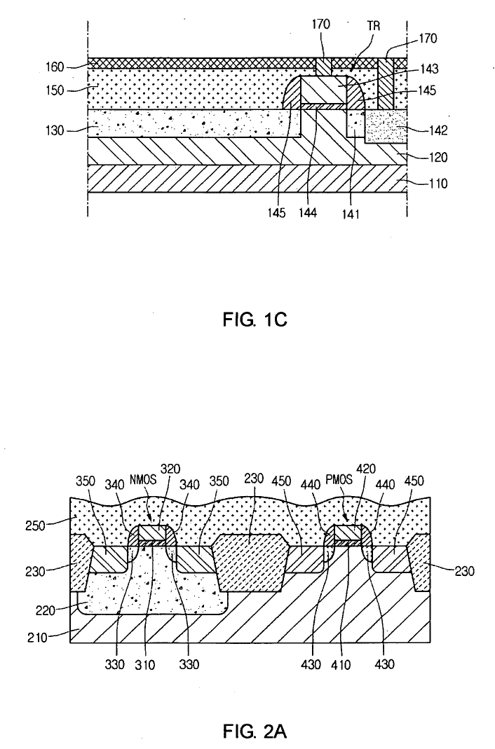

FIGS. 1A-1C are cross-sectional views illustrating a method of fabricating a CMOS image sensor.

As shown in FIG. 1A, a P-type epitaxial layer 120 is formed on a P-type semiconductor substrate 110. Then, an oxide film and a polysilicon layer are sequentially deposited on the P-type epitaxial layer 120. The oxide film and the polysilicon layer are patterned by a masking process to form a gate insulating film 144 and a gate electrode 143.

Then, low density N-type impurities are implanted into a predetermined region of the substrate and a region to the side of the gate using the gate electrode as a mask, thereby forming a photodiode 130 and an LDD region 141.

Then, a nitride film is formed to cover the gate electrode 143, and a gate spacer 145 is formed using an etching process such as an etch-back process. High density N-type impurities are implanted into the region of the epitaxial layer 120 to the side of the gate spacer 145, thereby forming a drain region 142.

Accordingly, the photodiode 130 and a transistor TR are formed on the P-type semiconductor substrate 110.

Then, an interlayer insulating layer 150 is formed to cover the photodiode 130 and the transistor TR. For example, boron-phosphorus silicate glass (BPSG) and phosphorus silicate glass (PSG) may be used as the interlayer insulating layer 150.

Then, as shown in FIG. 1B, after the interlayer insulating layer 150 is formed, the interlayer insulating layer 150 is planarized by a chemical mechanical polishing (CMP) process and a passivation film 160 is formed on the interlayer insulating layer 150.

The passivation film 160 is formed by depositing SiO₂ on the interlayer insulating layer 150 through a chemical vapor deposition (CVD) process. The passivation film 160 may be formed using, for example, a mixed gas containing SiH₄ and N₂O.

Then, the semiconductor substrate having the interlayer insulating layer 150 and the passivation film 160 formed on the photodiode 130 and the transistor TR undergoes an annealing process in a gas atmosphere containing boron (B) silicon (Si) or hydrogen (H). For example, the gas may comprise silane (SiₓH_{y}), hydrogen (H₂) or hydrogen boron (B₂H₆) In this embodiment, the semiconductor substrate undergoes an annealing process in a gas atmosphere of SiH₄, at a temperature that ranges from 300° C. to 420° C.

Since the P-type semiconductor substrate 110, the P-type epitaxial layer 120, the photodiode 130, the LDD region 141 and the drain region 142 undergo an annealing process in a gas atmosphere of SiH₄, a damaged silicon lattice is restored by the hydrogen included in the SiH₄ gas.

More specifically, any fluorine (F) existing in the P-type semiconductor substrate 110, P-type epitaxial layer 120, photodiode 130, LDD region 141, or drain region 142 that is damaging the silicon lattice combines with the silicon included in a SiH₄ gas. Accordingly, the fluorine (F) is discharged out of the P-type semiconductor substrate 110, P-type epitaxial layer 120, photodiode 130, LDD region 141, and drain region 142, and the structure of the lattice is restored.

Similarly, in an annealing process using hydrogen boron, the fluorine (F) combines with boron included in the hydrogen boron, in order to be removed.

Accordingly, the performance of the photodiode 130 and the transistor TR is improved. Further, since the P-type semiconductor substrate 110, the P-type epitaxial layer 120, the photodiode 130, the LDD region 141 and the drain region 142 undergo an annealing process in a gas atmosphere of SiH₄, the damaged silicon lattice can be efficiently restored in a low temperature annealing process.

As shown in FIG. 1C, via holes are formed to pass through the interlayer insulating layer 150 and the passivation film 160. Vias 170 fill the via holes and electrically connect to the transistor TR. Further, the vias 170 can be electrically connected to metal lines formed in a subsequent process.

### Method of Fabricating CMOS Transistor

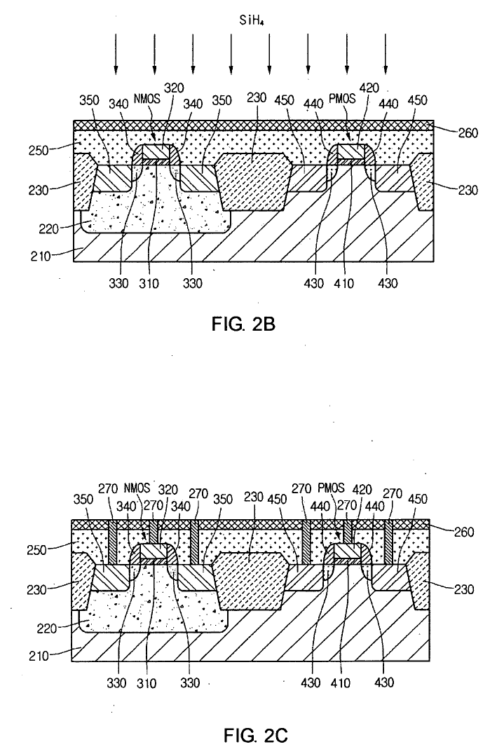

FIGS. 2A-2C are cross-sectional views illustrating a method of fabricating a CMOS transistor according to the present invention.

As shown in FIG. 2A, a device isolation film 230 is formed on an N-type semiconductor substrate 210 using a LOCOS process or an STI process in order to define an active region in which a semiconductor device is formed.

Then, P-type impurity ions are selectively implanted into each defined active region to form a P well 220. The active region having the P well 220 is defined as an N-type MOS transistor region, and the active region without the P well 220 is defined as a P-type MOS transistor region.

Then, the N-type semiconductor substrate 210 undergoes a thermal oxidation process, in order to grow an oxide film in the P-type and N-type MOS transistor regions. After polysilicon is deposited thereon, the polysilicon and the oxide film are patterned to form gate oxide films 310 and 410 and gate electrodes 320 and 420.

Then, low density P-type impurities are implanted into only the P-type MOS transistor region, thereby forming a P-type LDD region 430. Low density N-type impurities are implanted into only the N-type MOS transistor region, thereby forming an N-type LDD region 330.

Then, a nitride film is deposited on the entire surface of the N-type semiconductor substrate 210. Then, the nitride film undergoes anisotropic etching process such that the nitride film remains only on the side surface of the gate electrode, thereby forming gate spacers 340 and 440.

Then, high density P-type impurities are ion-implanted into the P-type MOS transistor region, forming a P-type source/drain region 450. Further, high density N-type impurities are ion-implanted into the N-type MOS transistor region, thereby forming an N-type source/drain region 350. 0037 Accordingly, a CMOS transistor including a P-type MOS transistor (PMOS) and an N-type MOS transistor (NMOS) are formed on the N-type semiconductor substrate 210.

After the CMOS transistor is formed, an interlayer insulating layer 250 is formed to cover the CMOS transistor. For example, BPSG and PSG may be used as the interlayer insulating layer 250.

As shown in FIG. 2B, after the interlayer insulating layer 250 is formed, the interlayer insulating layer 250 is smoothed by a chemical mechanical polishing (CMP) process and a passivation film 260 is formed on the interlayer insulating layer 250.

The passivation film 260 is formed by depositing SiO₂ on the interlayer insulating layer 250 through a chemical vapor deposition (CVD) process.

Then, the N-type semiconductor substrate 210 having the interlayer insulating layer 250 and the passivation film 260 formed on the CMOS transistor undergoes an annealing process in a gas atmosphere containing boron, silicon or hydrogen. Examples of gases that may be used in the annealing process are silane, hydrogen boron, and hydrogen. In this embodiment, the N-type semiconductor substrate 210 undergoes an annealing process in a gas atmosphere of SiH₄, at a temperature ranging from about 300° C. to about 420° C.

Since the N-type semiconductor substrate 210, P well 220, LDD regions 340 and 430, and source/drain regions 350 and 450 undergo an annealing process in a gas atmosphere of SiH₄, any damage to the silicon lattice may be restored by the hydrogen included in the SiH₄ gas.

Further, any fluorine existing in the N-type semiconductor substrate 210, P well 220, LDD regions 340 and 430, and source/drain regions 350 and 450 combines with silicon included in a SiH₄ gas, and is discharged.

In a case where the annealing process is performed in a hydrogen boron atmosphere, the fluorine in the layers of the semiconductors combines with boron included in the hydrogen boron and is removed.

Accordingly, the performance of the CMOS transistor is improved. Further, since the N-type semiconductor substrate 210, P well 220, LDD regions 340 and 430, and source/drain regions 350 and 450 undergo an annealing process in a gas atmosphere of SiH₄, the damaged silicon lattice can be efficiently restored in a low temperature annealing process.

As shown in FIG. 2C, via holes are formed to pass through the interlayer insulating layer 250 and the passivation film 260. Vias 270 fill the via holes and electrically connect to the CMOS transistor. Further, the vias 270 can be electrically connected to metal lines formed in a subsequent process.

It will be apparent to those skilled in the art that various modifications and variations can be made to the present invention without departing from the spirit or scope of the invention. Thus, it is intended that the present invention covers the modifications and variations of this invention provided they come within the scope of the appended claims and their equivalents.

What is claimed is:

1. A method of fabricating a semiconductor device comprising:
forming a transistor on a semiconductor substrate;
forming an interlayer insulating film on the semiconductor substrate to cover the transistor;
forming a passivation film on the interlayer insulating film; and
annealing the semiconductor substrate having the passivation film in a gas atmosphere comprising at least one gas selected from the group consisting of boron, silicon and hydrogen.

2. The method according to claim 1, wherein the interlayer insulating film comprises a boron-phosphorus silicate glass or a phosphorus silicate glass.

3. The method according to claim 1, the semiconductor substrate having the passivation film is annealed in the gas atmosphere at a temperature between 300° C. and 420° C.

4. The method according to claim 1, wherein the gas atmosphere comprises at least one gas selected from the group consisting of silane and hydrogen boron.

5. The method according to claim 1, wherein forming a transistor comprises forming a P-type MOS transistor in a region implanted with a first set of impurities and forming an N-type MOS transistor in a region implanted with second impurities.

6. The method according to claim 1, further comprising forming vias which are electrically connected to the transistor.

7. A method of fabricating a semiconductor device comprising:
forming a photodiode on a semiconductor substrate including a first region including first impurities and a second region including second impurities;
forming an interlayer insulating film on the semiconductor substrate to cover the photodiode;
forming a passivation film on the interlayer insulating film; and
annealing the semiconductor substrate having the passivation film in a gas atmosphere comprising at least one gas selected from the group consisting of boron, silicon, and hydrogen.

8. The method according to claim 7, wherein the interlayer insulating film comprises a boron-phosphorus silicate glass or a phosphorus silicate glass.

9. The method according to claim 7, wherein the semiconductor substrate having the passivation film undergoes an annealing process in the gas atmosphere at a temperature between 300° C. and 420° C.

10. The method according to claim 7, wherein the gas atmosphere comprises at least one gas selected from the group consisting of silane and hydrogen boron.

11. The method according to claim 7, further comprising forming vias to through the interlayer insulating film and the passivation film.

12. A method of fabricating a semiconductor device comprising:
forming a P-type MOS transistor in a first region of a semiconductor substrate by implanting the first region with a first set of impurities;
forming an N-type MOS transistor in a second region of a semiconductor substrate by implanting the second region with a second set of impurities;
forming an interlayer insulating film on the semiconductor substrate to cover the P-type MOS transistor and N-type MOS transistor;
forming a passivation film on the interlayer insulating film; and
annealing the semiconductor substrate having the passivation film in a gas atmosphere comprising at least one gas selected from the group consisting of boron, silicon and hydrogen at a temperature between 300° C. and 420° C.

13. The method according to claim 12, wherein the interlayer insulating film comprises a boron-phosphorus silicate glass or a phosphorus silicate glass.

14. The method according to claim 12, wherein the gas atmosphere comprises at least one gas selected from the group consisting of silane and hydrogen boron.

15. The method according to claim 12, further comprising forming vias which are electrically connected to the transistor.
